(19) United States
(12) Patent Application Publication
(10) Pub. No.: US 2011/0079896 A1
(43) Pub. Date: Apr. 7, 2011

(54) SEMICONDUCTOR DEVICE AND SEMICONDUCTOR DEVICE FABRICATION METHOD

(75) Inventors: Yoshiyuki SATOH, Kawasaki (JP); Kenji KOBAE, Kawasaki (JP); Kimio NAKAMURA, Kawasaki (JP); Takayoshi MATSUMURA, Kawasaki (JP); Kuniko ISHIKAWA, Kawasaki (JP)

(73) Assignee: FUJITSU LIMITED, Kawasaki-shi (JP)

(21) Appl. No.: 12/892,029

(22) Filed: Sep. 28, 2010

(30) Foreign Application Priority Data
Sep. 30, 2009 (JP) 2009-227399

(51) Int. Cl. H01L 23/488; H01L 21/44

(52) U.S. Cl. 257/737; 438/613; 257/E23.023; 257/E21.476

(57) ABSTRACT

A semiconductor device fabrication method, comprising the steps of: forming a solder portion on an electrode of a substrate on which a semiconductor chip is to be mounted; applying a resin layer onto the substrate to a thickness such that a top region of the solder portion is exposed; curing the resin layer; providing a thermosetting underfill material over a region where the semiconductor chip is to be mounted; placing an electrode of the semiconductor chip face down on the solder portion in such a manner that the electrode faces the solder portion; and heating the underfill material and the solder portion.

### CROSS REFERENCE TO RELATED APPLICATION

This application is based upon and claims the benefit of priority from the prior Japanese Patent Application NO. 2009-227399 filed on Sep. 30, 2009, the entire contents of which are incorporated herein by reference.

### FIELD

The embodiments discussed herein are related to a semiconductor device including a flip chip and a substrate and to a method of fabricating the semiconductor device.

### BACKGROUND

Semiconductor chips having a flip-chip structure that enables electrode pitch reduction have come into practical use to meet the demand for lower-cost, higher-density semiconductor devices. The flip-chip structure is characterized in that conductive bumps are placed on the electrodes of a semiconductor device. The reason why electrode pitch reduction may be achieved in the semiconductor chip having the flip-chip structure is that since the semiconductor chip having the flip-chip structure is connected to a substrate through the bumps, it does not request wide spacing between electrodes that would otherwise be needed for providing bonding wires.

Subsequently, a number of mounting methods for joining semiconductor chips having the flip-chip structure on a substrate have been proposed (see Japanese Laid-Open Patent Publication No. 2002-170853, for example). Among those methods, there is a joining method that uses solder as the material of contacts to join the bumps on the electrodes of semiconductor chips having the flip-chip structure to pads on the electrodes of a substrate.

The joining method that uses solder as the material of contacts involves heating for melting the solder. The joining method also involves applying pressure in order to bring the semiconductor chip close to the substrate while the solder is being melted. When the bumps on the substrate come close to the electrodes on the semiconductor chip, melted solder may flow along the bumps to become attached to the electrodes on the semiconductor chip. If the electrodes are made of aluminum, metal of the solder diffuses into the aluminum over time to reduce the conductivity of the aluminum, leading to faulty conduction. As a result, the long-term reliability of the joint between the semiconductor chip and the substrate will be lost.

In addition, when the bumps are brought into contact with melted solder, the solder is squeezed off the electrode on the substrate to come into contact with an adjacent electrode or solder on the substrate to electrically interconnect the adjacent electrodes. To allow for such squeeze-off of the solder, it is requested to widen the spacing between the electrodes on the substrate and the semiconductor chip, which inhibits reduction of the electrode pitch.

Furthermore, after completion of joint with bumps and solder, the solder may melt again during a heating process for mounting additional components onto the substrate. If there is a void in a cured underfill material, the melted solder may flow along the void to come into contact with an adjacent electrode. Allowing for voids in the underfill material makes it further difficult to reduce the electrode pitch.

### SUMMARY

According to one aspect of the embodiments, there is provided a semiconductor device fabrication method including: forming a solder portion on an electrode of a substrate on which a semiconductor chip is to be mounted; applying a resin layer onto the substrate to a thickness such that a top region of the solder portion is exposed; curing the resin layer; providing a thermosetting underfill material over a region where the semiconductor chip is to be mounted; placing an electrode of the semiconductor chip face down on the solder portion so that the electrode faces the solder portion; and heating the underfill material and the solder portion.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIGS. 1A to 1D, 2A to 2D are diagrams of a semiconductor device fabrication method according to a first exemplary embodiment, illustrating processes from the start to the step of forming an electrode structure of a semiconductor chip and from the start to the step of forming an electrode structure of a substrate;

FIGS. 3A to 3C are diagrams of the semiconductor device fabrication method according to the first exemplary embodiment, illustrating a process from resin injection to the end of the process;

FIGS. 4A to 4D are diagrams of a semiconductor device fabrication method according to a second exemplary embodiment, illustrating only the steps unique to the second exemplary embodiment;

FIGS. 5A and 5B are diagrams of a semiconductor device fabrication method according to a third exemplary embodiment, illustrating only the steps unique to the third exemplary embodiment; and

FIGS. 6A and 6B are diagrams of a semiconductor device fabrication method according to a fourth exemplary embodiment that illustrates an ultrasonic vibration step op12.

### DESCRIPTION OF EMBODIMENTS

The present invention encompasses embodiments described below as well as modifications to the design of the embodiments which occur to those skilled in the art and embodiments in which any of the components of the embodiments are rearranged. The present invention is not limited to the exemplary embodiments described below and also encompasses embodiments in which any of the components of the embodiments are replaced with other components that have the same effects of the components.

### First Exemplary Embodiment

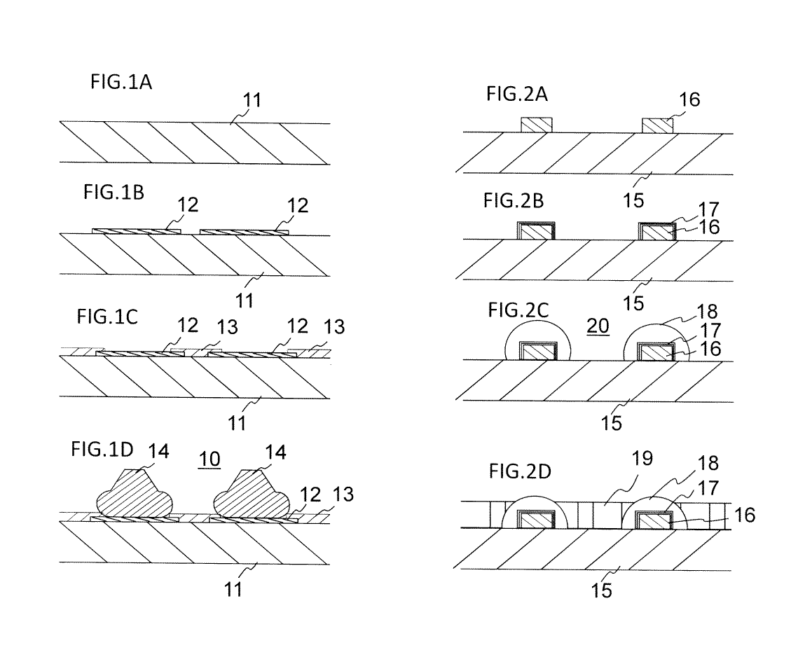

FIGS. 1A to 1D, 2A to 2D are flowcharts of a semiconductor device fabrication method according to a first exemplary embodiment, illustrating processes from the start to the step of forming an electrode structure of a semiconductor chip and from the start to the step of forming an electrode structure of a substrate, and diagrams explaining the individual steps. The semiconductor device includes the semiconductor chip 11 and the substrate 15 on which the semiconductor chip 11 is mounted.

FIGS. 1A to 1D are diagrams of the process from the start to the step of forming the electrode structure of the semiconductor chip.

FIGS. 1A to 1D are cross-sectional views of electrodes and their surrounding regions of the semiconductor chip 11 in the process of forming the electrode structure of the semiconductor chip 11.

The electrode structure 10 of the semiconductor chip 11 is formed by the steps of preparing the chip, forming electrodes, providing windows, and forming metal bumps. The electrode structure 10 of the semiconductor chip 11 herein is a structure including electrodes 12, an insulating layer 13, and metal bumps 14.

FIG. 1A is a cross-sectional view of the semiconductor chip 11. In the preparation step, the semiconductor chip 11 including semiconductor elements, interconnects, and insulating layers for electrically insulating interconnects is prepared by a conventional semiconductor chip fabrication process. While the semiconductor chip 11 is a semiconductor substrate made of silicon (Si), it may be a substrate made of a semiconductor compound such as gallium arsenide or other semiconductor.

FIG. 1B illustrates the cross section of the semiconductor chip 11 on which electrodes 12 have been formed. In the electrode forming step, electrodes 12 connected to interconnects of the semiconductor chip 11 for receiving signals from an external source are formed. The electrodes 12 are formed by forming a metal layer of aluminum (Al) on top of an insulating layer and forming the metal layer into an electrode pattern.

FIG. 1C illustrates the cross section after an insulating layer 13 insulating electrodes 12 has been formed and the windows have been provided. In the step of providing the windows, the insulating layer 13 of an organic material is formed on the electrodes 12 and the semiconductor chip 11 and then windows that reach the electrodes 12 are formed in the insulating layer 13.

FIG. 1D illustrates the cross section after metal bumps 14 have been formed. In the metal bump forming step, metal wires primarily made of gold (Au) are bonded to the electrodes 12 exposed in the windows, the metal wires are pressed against the electrodes 12 to form metal balls in the windows, and the metal wires projecting from the metal balls are cut to form the metal bumps 14. The electrode structure 10 of the semiconductor chip is completed with the completion of the metal bump forming step.

FIGS. 2A to 2D are diagrams of the process from the start to the step of forming the electrode structure of the semiconductor chip.

FIGS. 2A to 2D are cross-sectional views of an electrode region of the substrate 15 in the process of forming the electrode structure of the substrate 15. The electrode structure 10 of the substrate 15 is formed by the step of preparing the substrate, the step of forming a metal film, and the step of forming solder. The electrode structure 10 of the substrate 15 herein is a structure including electrodes 16, a metal film 17, pieces of solder 18, and a resin layer 19.

FIG. 2A is a cross-sectional view of the substrate 15. In the substrate preparing step, the substrate 15 is prepared which includes an insulating layer, a surface interconnect layer on the substrate 15 in which electrodes 16 are formed, an interconnect layer sandwiched between insulating layers, and via holes which pass through the insulating layer and interconnect the interconnect layers. The surface interconnect layer and the interconnect layers of the substrate 15 are made of metal containing copper (Cu). The insulating layers of the substrate 15 are made of glass epoxy resin. However, the insulating layers may be made of other insulating resin or resin containing a material having a high thermal conductivity such as carbon fiber or inver.

FIG. 2B illustrates the cross-section after the metal film 17 has been formed on the electrodes 16 formed from the surface interconnect layer on the substrate 15. In the metal film forming step, electrolytic plating is applied to the electrodes 16 containing copper (Cu) to plate the electrodes 16 with a film consisting of two layers: a nickel (Ni) layer and a gold (Au) layer.

FIG. 2C illustrates the cross-section after pieces of solder 18 have been formed on the electrodes 16. In the step of forming the pieces of solder 18, a mask with windows that expose the electrodes 16 is formed on the substrate 15, the electrodes 16 are coated with a solder layer by electroless plating or a squeeze method, and then the mask is removed to form the pieces of solder 18. The solder 18 is preferably low-temperature solder made of a material such as a eutectic alloy of tin (Sn) and silver (Ag) or bismuth (Bi). This is because a low melting temperature of the pieces of solder 18 will inhibit thermal deformation of the semiconductor device which would be caused by a difference in thermal expansion rate between the substrate 15 made of a material such as glass epoxy and the semiconductor chip 11 made of a material such as silicon. The electrode structure 20 of the substrate is completed with the completion of the solder forming step.

FIG. 2D illustrates the cross-section after a resin layer 19 has been formed on the substrate 15. In the substrate flattening step op8, resin is applied onto the substrate 15, the resin is cured, and then the pieces of solder 18 are exposed in the upper surface of the thus formed resin layer 19. One feature of the present invention is that as a result of the substrate flattening step op8, the resin layer 19 is formed coherently with the pieces of solder 18.

The resin layer 19 is preferably made of a resist material or epoxy resin that has heat resistance up to approximately 220° C. after being cured. This is because the melting temperature of normal solder is approximately 200° C., while mention has been made of the melting point of low-temperature solder in the foregoing.

The resin is preferably cured by heating, irradiation with light, or solvent evaporation. If the resin is cured by heating, the heating temperature requested for curing is preferably lower than the melting temperature of the solder 18. This is because if the resin has not been cured at the heating step, traveling of solder 18 may not be inhibited when the heating temperature increases to melt the solder 18.

The resin layer 19 is preferably formed to a substantially uniform thickness on the substrate and thinner than the height of the top regions of the pieces of solder 18. The pieces of solder 18 may be exposed in the top surface of the resin layer 19 by using a spin coater to cause applied resin to spin off until a thickness that expose the top regions of the pieces of solder 18 is achieved. Alternatively, the pieces of solder 18 may be exposed in the top surface of the resin layer 19 by isotropically etching the resin layer applied and cured on the pieces of solder 18 and the substrate 15 until the top regions of the pieces of solder 18 are exposed. In either case, the pieces of solder 18 will be coherent with the resin layer 19 with no space between them. Accordingly, the resin layer 19 prevents traveling of the solder 18 in melting.

The resin layer 19 may be made of a resin of a type different from an underfill material 21 and may be cured under conditions different from the conditions under which the underfill material 21 is cured. Therefore, the possibility of occurrence of voids in the resin layer 19 may be made lower than that in the underfill material 21.

While the resin layer 19 is made of an organic material in the foregoing, an inorganic material layer may be formed by using an inorganic insulating material such as silsesquioxane hydroxide instead of the resin layer 19. Alternatively, a layer may be made by using an inorganic insulating material dissolved in an organic material, for example methylsilsesquioxane, instead of the resin layer 19.

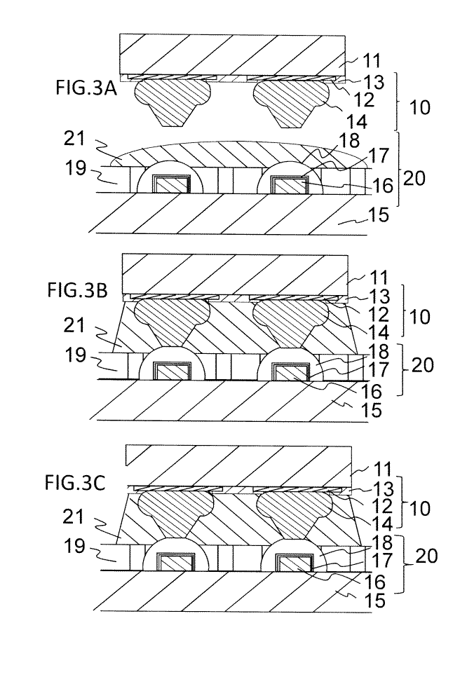

FIGS. 3A through 3C are diagrams (continued from FIG. 1A) illustrating steps of the semiconductor device fabrication method according to the first exemplary embodiment, from the underfill material injection to completion of the fabrication of the semiconductor device.

The process of the semiconductor device fabrication method includes a resin injecting step of injecting an underfill material onto the resin layer 19 illustrated in FIG. 3A, an electrode connecting step of brining the metal bumps 14 of the semiconductor chip 11 into contact with the pieces of solder 18 of the substrate 15, and a heating step of heating the underfill material to cure the underfill material.

FIG. 3A is a cross-sectional view illustrating the underfill material 21 injected onto the resin layer 19. In the resin injecting step, the underfill material 21 is injected between the substrate 15 and the semiconductor chip 11. The underfill material 21 may be any thermosetting resin, for example epoxy resin. The underfill material 21 may contain insulating spherical filler particles.

FIG. 3B illustrates the cross section after the metal bumps 14 have been brought into contact with the pieces of solder 18 in the electrode connecting step.

In the electrode connecting step, the metal bumps 14 are connected to the pieces of solder 18 under the underfill material 21 through the underfill material 21. The volume of the underfill material 21 is preferably such that the gap between the substrate 15 and the semiconductor chip 11 is filed with the underfill material 21 when the metal bumps 14 are connected to the pieces of solder 18 as described above.

FIG. 3C illustrates the cross section after the underfill material 21 has been cured in the heating step. In the heating step, the entire combination of the substrate 15 and the semiconductor chip 11 is heated to cure the underfill material 21 and to melt the pieces of solder 18. The heating of the entire combination of the substrate 15 and the semiconductor chip 11 is performed by a heater provided in a mounting tool that supports the substrate 15 and the semiconductor chip 11, for example. Then, in the heating step, the entire combination of the substrate 15 and the semiconductor chip 11 is cooled, so that an alloy of the metal in the metal bumps 14 and the metal in the melted pieces of solder 18 is formed to cause the metal bumps 14 and the pieces of solder 18 to stick to each other. Since the resin layer 19 does not melt while the pieces of solder 18 are melted, the melted solder 18 do not flow toward an adjacent electrode 16 on the substrate 15. In addition, since the metal bumps 14 are connected to the top region of the pieces of solder 18, wicking length of the solder 18 may be minimized. The curing temperature of the underfill material 21 is preferably lower than the melting temperature of the solder 18 because the underfill material 21 cures before the solder 18, whereby wicking of the solder 18 may be prevented.

As has been described, the semiconductor device fabrication method according to the first exemplary embodiment includes:

forming electrodes to be connected to a semiconductor chip and metal bumps to be connected to the electrodes;

forming electrodes to be connected to a substrate and solder portions to be connected to the electrodes;

forming a resin layer on the substrate coherently with the solder portions to a thickness such that a top portion of each of the solder portions is exposed;

providing an underfill material on the resin layer and the solder portions;

placing the solder portions on the substrate face down on the metal bumps of the semiconductor chip in such a manner that the solder portions face the metal bumps and bringing the solder portions into contact with the metal bumps; and

heating the substrate and the semiconductor.

Since the resin layer 19 does not melt while the solder 18 is melting, the resin layer 19 inhibits the solder 18 from flowing toward an adjacent electrode 16 on the substrate 15. Thus, traveling of the solder 18 toward the adjacent electrode may be prevented. Since the solder 18 and the resin layer 19 are formed coherently, there may be no place for the solder 18 to travel.

The resin layer 19 is preferably made of a material, such as a resist material or epoxy resin, that resists, after being cured, to the melting temperature of the solder 18.

Furthermore, the heating temperature requested for curing the resin is preferably lower than the melting temperature of the solder 18.

A semiconductor device fabricated by the fabrication method described above includes:

a semiconductor chip;

metal bumps formed on electrodes on the semiconductor chip;

a substrate placed so as to face the electrodes on the semiconductor chip and having electrodes facing the electrodes on the semiconductor chip;

solder portions formed on the electrodes on the substrate;

a resin layer having a thickness such that a top region of each of the solder portions is exposed and being formed on the substrate coherently with the solder portions; and

an underfill material provided between the resin layer and the semiconductor chip.

When the component mounting step involving heating to a temperature at which the solder 18 melts is performed after joining the solder 18 and the metal bumps 14 together, the resin layer 19 prevents the melted solder 18 from flowing toward an adjacent electrode. In particular, since the resin layer 19 made of a material different from the underfill material 21 is provided between the pieces of solder 18 on the substrate 15, the possibility of occurrence of voids may be reduced. Because of the avoidance of voids, traveling of solder 18 through voids which would otherwise be present in the resin layer 19 may be prevented.

Furthermore, since the metal bumps 14 are connected to the top region of each piece of solder 18, the wicking length of the solder 18 may be reduced. Accordingly, vertical traveling of the solder 18 through the metal bumps 14 may be inhibited.

### Second Exemplary Embodiment

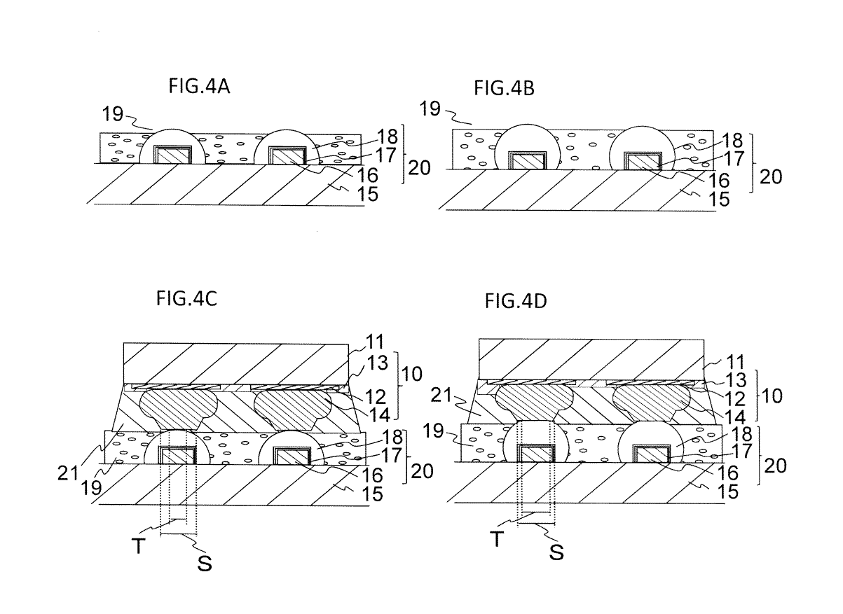

FIGS. 4A to 4D are diagrams illustrating a semiconductor device fabrication method according to a second exemplary embodiment. The semiconductor device fabrication method of the second exemplary embodiment differs from the semiconductor device fabrication method of the first exemplary embodiment in that the thickness of the resin layer 19 is adjusted at the substrate flattening step so that the area of the top region of each piece of solder 18 exposed in the upper surface of the resin layer 19 becomes smaller than the area of the bottom of each metal bump 14. The area of the top region of each piece of solder 18 may be defined for example as the area of a cross section of the piece of solder 18 taken at the level of the main surface of the resin layer 19. The other steps of the semiconductor device fabrication method of the second exemplary embodiment are the same as those of the first exemplary embodiment and therefore the description of the same steps will be omitted.

FIG. 4A is a cross-sectional view illustrating the relationship between an electrode structure 20 of a substrate 15 that has smaller pieces of solder 18 and the thickness of the resin layer 19. Referring to FIG. 4A, the resin layer 19 formed thin proportionally to the size of the pieces of solder 18.

FIG. 4B is a cross-sectional view illustrating the relationship between an electrode structure 20 of a substrate 15 that has larger pieces of solder 18 and the thickness of the resin layer 19. Referring to FIG. 4B, the resin layer 19 is formed thick proportionally to the size of the pieces of solder 18.

FIG. 4C is a cross-sectional view of a semiconductor device fabricated with the electrode structure 20 of the substrate 15 that has the small pieces of solder 18 illustrated in FIG. 4A. The area of the bottom of each metal bump 14 is larger than the area of the exposed top region of the piece of solder 18. It may be seen from the cross-sectional view in FIG. 4C that the length T of the top region of the piece of solder 18 in the cross-section is shorter than the length S of the bottom of the metal bump 14.

FIG. 4D is a cross-sectional view of a semiconductor device fabricated with the electrode structure 20 of the substrate 15 that has the large pieces of solder 18. As in the electrode structure 20 in FIG. 4C, the area of the bottom of each metal bump 14 is larger than the area of the exposed top region of the piece of solder 18. The length T of the top region of the piece of solder 18 in the cross-section is shorter than the length S of the bottom of the metal bump 14.

By making the area of the bottom of each metal bump 14 larger than the area of the top region of the piece of solder 18 as described above, the wicking length of the solder 18 may be reduced because the bottom of the metal bump 14 prevents wicking of the solder 18.

As has been described above, the semiconductor device fabrication method according to the second exemplary embodiment is characterized in that the top region of each piece of solder 18 is exposed at the substrate flattening step in the process of the semiconductor device fabrication method of the first exemplary embodiment, in such a manner that the area of the metal bump 14 becomes larger than the area of the exposed top region of the solder 18.

In the semiconductor device fabrication method of the second exemplary embodiment, the bottom of each metal bump 14 more reliably inhibits wicking of the solder 18 to inhibit vertical traveling of the solder 18 than in the semiconductor device fabrication method of the first exemplary embodiment.

### Third Exemplary Embodiment

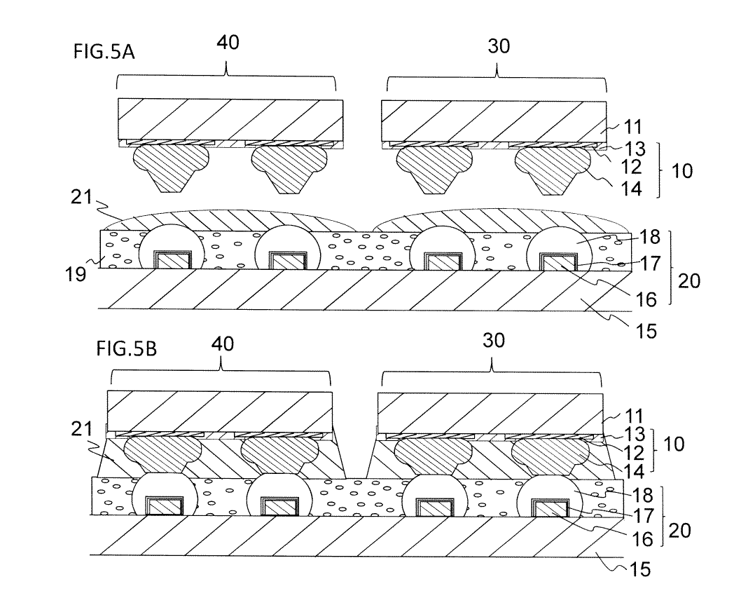

FIGS. 5A and 5B are diagrams of a semiconductor device fabrication method according to a third exemplary embodiment, illustrating only the steps unique to the third exemplary embodiment. FIGS. 5A and 5B illustrate cross-sectional views of semiconductor chip assemblies 30 and 40, a substrate 15, and two electrode structures 20 of the substrate 15.

The substrate 15 includes an electrode structure 20 for the semiconductor chip assembly 30 and another electrode structure 20 for the semiconductor chip assembly 40 on the substrate 15. The semiconductor chip assemblies 40 and 30 are mounted on the substrate 15 correspondingly to their respective electrode structures 20. An underfill material 21 is provided between each of the semiconductor chip assemblies 30 and 40 and a resin layer 19 on the substrate 15.

The semiconductor chip assembly 30 includes a semiconductor chip 11 and a semiconductor chip electrode structure 10. The semiconductor chip electrode structure 10 includes electrodes 12, an insulating layer 13, and metal bumps 14. The semiconductor chip assembly 40 has a structure similar to the semiconductor chip assembly 30.

The resin layer 19 is provided on the substrate 15 continuously for both electrode structures 20. The top region of each piece of solder 18 of the electrode structures 20 is exposed in the top surface of the resin layer 19.

FIG. 5A is a cross-sectional view in which the metal bumps 14 of the semiconductor chips 11 have been placed so as to face the corresponding solder portions of the substrate 15 and the underfill material has been injected.

The semiconductor device fabrication method of the third exemplary embodiment differs from the semiconductor device fabrication method of the first exemplary embodiment in that the metal bumps of multiple semiconductor chips 11 are placed so as to face the solder portions of the substrate 15 in the resin injection step. Then, the electrode connecting step and the heating step of heating and curing the underfill material are applied to the entire combination of the multiple semiconductor chips 11 and the substrate 15 on which the semiconductor chips 11 have been placed. The entire combination of the multiple semiconductor chips 11 and the substrate 15 on which the semiconductor chips 11 have been placed are preferably heated by contact heating using a heating head system in which a heater is provided. It is also preferable that the entire combination of the multiple semiconductor chips 11 and the substrate 15 on which the semiconductor chips 11 are placed are heated in a heating oven included in a reflow system.

FIG. 5B is a cross-sectional view illustrating the substrate 15 on which the semiconductor chips 11 have been placed and to which the heating step of heating and curing the underfill material has been applied.

The rest of the semiconductor device fabrication method of the third exemplary embodiment is the same as the semiconductor device fabrication method of the first exemplary embodiment and therefore the description of the rest of the method will be omitted.

As has been described above, the semiconductor device fabrication method of the third exemplary embodiment includes the step of placing the metal bumps of multiple semiconductor chips so as to face the corresponding solder portions on the substrate and bringing the metal bumps into contact with the solder portions and the step of heating the substrate and the multiple semiconductor chips, in place of the corresponding steps of the semiconductor device fabrication method of the first exemplary embodiment.

If the heating step of heating and curing the underfill material were performed each time a semiconductor chip 11 is mounted on the substrate, the joint between the semiconductor chip(s) 11 previously mounted and the substrate 15 would be repeatedly thermally deformed. As a result, the reliability of the semiconductor device in which the multiple semiconductor chips 11 are mounted on the substrate 15 would decrease. In the method of the third exemplary embodiment, the heating step is performed on the semiconductor chips 11 in contact with the substrate 15 at a time. Therefore, thermal deformation is not repeated and a higher reliability may be achieved.

### Fourth Exemplary Embodiment

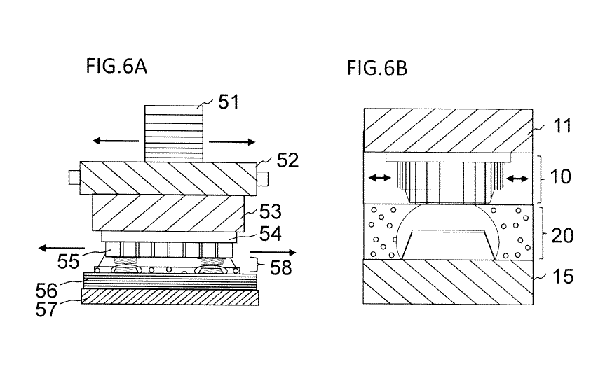

FIGS. 6A and 6B are diagrams of a semiconductor device fabrication method according to a fourth exemplary embodiment for illustrating an ultrasonic vibration step. The process from the start to the step of electrode connecting step of the semiconductor device fabrication method of the fourth exemplary embodiment is the same as the semiconductor device fabrication method of the first exemplary embodiment. Referring to the diagrams of FIGS. 6A and 6B, the semiconductor device fabrication method of the fourth exemplary embodiment is characterized by including an ultrasonic vibration step between the electrode connecting step and the heating step. The heating step is similar to the heating step of the semiconductor device fabrication method of the first exemplary embodiment and therefore the description of step will be omitted.

FIG. 6A is a cross-sectional view illustrating application of ultrasonic vibration to a semiconductor chip 55 in the ultrasonic vibration step op12. FIG. 6B depicts an ultrasonic generator 51, an ultrasonic oscillator 52, a bonding tool 53, a chip press 54, a semiconductor chip 55, a mounting structure 58, a substrate 56, and a platform 57.

The ultrasonic oscillator 52 receives ultrasonics generated by the ultrasonic generator 51 and oscillates. The oscillation of the ultrasonic oscillator 52 propagates to the bonding tool 53 and the chip press 54 to vibrate the semiconductor chip 55. The vibration of the semiconductor chip 55 in turn vibrates a semiconductor chip electrode structure 10 in the mounting structure 58.

FIG. 6B is a cross-sectional view of a joint between a solder 18 and a metal bump 14 in the ultrasonic vibration step. Since the electrode structure 10 of the semiconductor chip 55 vibrates, the metal bump 14 also vibrates.

The ultrasonic vibration step may remove residues of resin remaining after the formation of the resin layer 19 or residues of underfill material 21 at the contact surface between the metal bumps 14 and the pieces of solder 18.

The subsequent heating step melts the solder 18 so that an alloy of the metal in the metal bumps 14 and the metal in the solder 18 is formed to stick the solder 18 and the metal bumps 14 together. If residues remaining after the formation of resin layer 19 or residues of underfill material 21 were not removed from the contact surface between the solder 18 and the metal bumps 14, the formation of the alloy would be difficult.

While ultrasonic vibration is provide to the metal bumps 14 in the foregoing, a similar ultrasonic generator 51 may be used to provide ultrasonic vibration to the pieces of solder 18 on the substrate 15.

The semiconductor device fabrication method of the fourth exemplary embodiment described above includes the ultrasonic vibration step in addition to the steps of the semiconductor device fabrication method of the first exemplary embodiment.

The addition of the ultrasonic vibration step may remove residues of resin or residues of the underfill material between the pieces solder 18 and the metal bumps 14 after the pieces of solder 18 and the metal bumps 14 have been brought into contact with each other. As a result, the degree of cohesion between the pieces of solder 18 and the metal bumps 14 in the subsequent heating step may be increased.

The semiconductor device fabrication method of the fourth exemplary embodiment also has the advantageous effects of the semiconductor device fabrication method of the first exemplary embodiment since the semiconductor device fabrication method of the fourth exemplary embodiment include the semiconductor device fabrication method of the first embodiment.

According to the embodiments, a semiconductor device fabrication method and a semiconductor device fabricated by the method that are capable of preventing traveling of melted solder on a substrate during fabrication of the semiconductor device may be provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device fabrication method, comprising:
forming a solder portion on an electrode of a substrate;
applying a resin layer onto the substrate to a thickness such that a top region of the solder portion is exposed from an upper plane of the resin layer;
curing the resin layer;
providing a thermosetting underfill material on the resin layer and the top region of the solder portion;
placing a metal bump on the semiconductor chip so as to face down on the solder portion; and
heating the underfill material and the solder portion.

2. The semiconductor device fabrication method according to claim 1, wherein the resin layer is cured before the solder portion is melted.

3. The semiconductor device fabrication method according to claim 1, wherein the curing temperature of the underfill material is lower than the melting temperature of the solder portion.

4. The semiconductor device fabrication method according to claim 2, wherein the curing temperature of the underfill material is lower than the melting temperature of the solder portion.

5. The semiconductor device fabrication method according to claim 1, wherein an end face of the metal bump has a larger area than a cross section of the solder portion taken at the upper plane of the resin layer.

6. The semiconductor device fabrication method according to claim 1, further comprising mounting the semiconductor chip on the substrate by applying ultrasonic vibration.

7. A semiconductor device comprising:
a semiconductor chip including a metal bump thereon;
a substrate including a electrode thereon;
a solder portion disposed on the electrode, and coupled to the metal bump;
a resin layer disposed on the substrate such that a top region of the solder portion is exposed from an upper plane of the resin layer; and
an underfill material disposed on the resin layer.

8. The semiconductor device according to claim 7, wherein the resin layer is made of a material different from the underfill material.

9. The semiconductor device according to claim 7, wherein an end face of the metal bump has a larger area than a cross section of the solder portion taken at the upper plane of the resin layer.
